(19) United States
(12) Patent Application Publication
(10) Pub. No.: US 2025/0126796 A1
(43) Pub. Date: Apr. 17, 2025

(54) SEMICONDUCTOR MEMORY DEVICE AND METHOD OF MANUFACTURING SEMICONDUCTOR MEMORY DEVICE

(71) Applicant: SK hynix Inc., Icheon-si Gyeonggi-do (KR)

(72) Inventors: Eun Seok CHOI, Icheon-si Gyeonggi-do (KR); Jae Young OH, Icheon-si Gyeonggi-do (KR)

(73) Assignee: SK hynix Inc., Icheon-si Gyeonggi-do (KR)

(21) Appl. No.: 18/646,983

(22) Filed: Apr. 26, 2024

(30) Foreign Application Priority Data
Oct. 16, 2023 (KR) 10-2023-0137747

(51) Int. Cl. H10B 43/35; H01L 23/00; H01L 25/00; H01L 25/065; H01L 25/18; H10B 41/27; H10B 41/35; H10B 43/27; H10B 80/00

(52) U.S. Cl. CPC H10B 43/35; H01L 24/08; H01L 24/80; H01L 25/0657; H01L 25/18; H01L 25/50; H10B 41/27; H10B 41/35; H10B 43/27; H10B 80/00; H01L 2224/08145; H01L 2224/80895; H01L 2224/80896; H01L 2924/1431; H01L 2924/14511

(57) ABSTRACT

Provided herein is a semiconductor memory device and a method of manufacturing the same. The semiconductor memory device includes a channel layer, and a source select line surrounding at least a part of the channel layer. A p-type impurity is locally doped in the part of the channel layer or a gate insulating layer includes a first member interposed between the channel layer and the source select line and aligned with a data storage layer.

### CROSS-REFERENCE TO RELATED APPLICATION

The present application claims priority under 35 U.S.C. § 119 (a) to Korean patent application number 10-2023-0137747 filed on Oct. 16, 2023, in the Korean Intellectual Property Office, the entire contents of which application is incorporated herein by reference.

### BACKGROUND

### 1. Technical Field

Various embodiments of the present disclosure generally relate to a semiconductor memory device and a method of manufacturing a semiconductor memory device, including, but not limited to, a three-dimensional (3D) semiconductor memory device and a method of manufacturing a three-dimensional semiconductor memory device.

### 2. Related Art

Semiconductor memory devices are included in a small electronic device as well as electronic devices in various fields such as automobiles, medical fields, or data centers. Thus, there is a growing demand for semiconductor memory devices.

The semiconductor memory device may include a memory cell for storing data. In order to achieve a high-capacity semiconductor memory device, technical development for a three-dimensional semiconductor memory device, which includes memory cells arranged in three dimensions, is actively underway.

A drain select transistor, a source select transistor, and a plurality of memory cells connected in series between the drain select transistor and the source select transistor forms a memory cell string. The memory cell string of the three-dimensional semiconductor memory device is controlled by a plurality of conductive layers that are stacked and spaced apart from each other and a channel layer that extends through the plurality of conductive layers. The plurality of conductive layers may be used as a drain select line serving as a gate electrode of the drain select transistor, a source select line serving as a gate electrode of the source select transistor, and a word line serving as a gate electrode of each memory cell.

### SUMMARY

An embodiment of the present disclosure may provide for a semiconductor memory device. The semiconductor memory device may include a channel layer including a first area, a second area extending from the first area in a first direction, and a third area extending from the second area in the first direction, wherein the second area contains a p-type impurity, a plurality of word lines stacked along a side wall of the first area and spaced apart from each other in the first direction, a source select line spaced apart from the plurality of word lines in the first direction, at least a section of the source select line surrounding at least a part of the second area in the channel layer, a data storage layer interposed between the plurality of word lines and the channel layer, and a tunnel insulating layer interposed between the data storage layer and the channel layer and extending in the first direction beyond the data storage layer such that the tunnel insulating layer is interposed between the channel layer and the source select line.

An embodiment of the present disclosure may provide for a semiconductor memory device. The semiconductor memory device may include a channel layer extending in a first direction, a plurality of word lines stacked along a side wall of the channel layer and spaced apart from each other in the first direction, a source select line spaced apart from the plurality of word lines in the first direction and spaced apart from the side wall of the channel layer in a second direction perpendicular to the first direction, a doped semiconductor layer spaced apart from the source select line in the first direction and contacting an end of the channel layer, a gate insulating layer including a first member interposed between the channel layer and the source select line, and a data storage layer interposed between the plurality of word lines and the channel layer. The first member of the gate insulating layer is aligned with the data storage layer in the first direction.

An embodiment of the present disclosure may provide for a method of manufacturing a semiconductor memory device. The method may include forming a stacked body including a first interlayer insulating layer that has a first surface and a second surface facing in opposite directions and a plurality of word lines alternately stacked with a plurality of second interlayer insulating layers over the first surface of the first interlayer insulating layer, forming a cell plug including a channel layer that extends through the stacked body and has a protrusion extending beyond the second surface of the first interlayer insulating layer, a tunnel insulating layer including a first area interposed between the channel layer and the stacked body and a second area covering the protrusion of the channel layer, a data storage layer extending along the first area and the second area of the tunnel insulating layer, and a blocking insulating layer extending along the data storage layer, wherein the data storage layer is interposed between the tunnel insulating layer and the blocking insulating layer, sequentially removing a portion of the blocking insulating layer and a portion of the data storage layer to expose the second area of the tunnel insulating layer, forming a preliminary doped area in the channel layer by injecting an impurity of a first conductivity type into an area of the channel layer surrounded by at least the second surface of the first interlayer insulating layer, and forming a source select line over the second surface of the first interlayer insulating layer.

An embodiment of the present disclosure may provide for a method of manufacturing a semiconductor memory device. The method may include forming a stacked body including a first interlayer insulating layer that has a first surface and a second surface facing in opposite directions and a plurality of word lines alternately stacked with a plurality of second interlayer insulating layers over the first surface of the first interlayer insulating layer, forming a cell plug including a channel layer that extends through the stacked body and has a protrusion extending beyond the second surface of the first interlayer insulating layer, a tunnel insulating layer including a first area interposed between the channel layer and the stacked body and a second area covering the protrusion of the channel layer, a data storage layer extending along the first area and the second area of the tunnel insulating layer, and a blocking insulating layer extending along the data storage layer, wherein the data storage layer is interposed between the tunnel insulating layer and the blocking insulating layer, sequentially removing a portion of the blocking insulating layer and a portion of the data storage layer to expose the second area of the tunnel insulating layer, forming a gate insulating layer that covers the exposed second area of the tunnel insulating layer, and forming a source select line over the gate insulating layer.

An embodiment of the present disclosure may provide for a semiconductor memory device. The semiconductor memory device may include a channel layer extending in a first direction and including a first area having a doped impurity; a plurality of word lines stacked along the channel layer and spaced apart from each other in the first direction; a source select line spaced apart from the plurality of word lines in the first direction and spaced apart from the side wall of the channel layer in a second direction perpendicular to the first direction; a doped semiconductor layer contacting an end of the channel layer; a gate insulating layer including a first member interposed between the channel layer and the source select line. The first area may be at least partially disposed at a level of the source select line. A thickness of the gate insulating layer may establish threshold voltage characteristics for a source select transistor associated with the source select line.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory cell array according to an embodiment of the present disclosure.

FIG. 3A and FIG. 3B are sectional views illustrating the semiconductor memory device according to an embodiment of the present disclosure.

FIG. 4 is a sectional view illustrating the semiconductor memory device according to an embodiment of the present disclosure.

FIG. 5A is a sectional view of a semiconductor memory device during the formation of a first structure according to an embodiment of the present disclosure.

FIG. 5B is a sectional view of a semiconductor memory device during a bonding process between the first structure and a second structure according to an embodiment of the present disclosure.

FIG. 6A and FIG. 6B are sectional views of a semiconductor memory device during processes of exposing a portion of a tunnel insulating layer according to an embodiment of the present disclosure.

FIG. 7A, FIG. 7B, FIG. 7C, FIG. 7D, and FIG. 7E are sectional views illustrating an embodiment of a semiconductor memory device during processes performed on the semiconductor memory device of FIG. 6B.

FIG. 8A, FIG. 8B, FIG. 8C, FIG. 8D, and FIG. 8E are sectional views illustrating an embodiment of a semiconductor memory device during processes performed after the process applied to the semiconductor memory device of FIG. 6B.

FIG. 9 is a block diagram illustrating an electronic system including a semiconductor memory device according to an embodiment of the present disclosure.

### DETAILED DESCRIPTION

Specific structural or functional descriptions of embodiments according to the concept of the present disclosure, disclosed in the present specification or application, are exemplified to explain the embodiments according to the concepts of the present disclosure. The embodiments according to the concepts of the present disclosure should not be construed as limited to embodiments described in the present specification or application and may be modified in various forms and replaced with other equivalent embodiments.

Although the terms “first,” “second,” and so forth may be used herein to describe various elements, these elements should not be limited by these terms. These terms are only used to distinguish one element from another element, and the order or number of components is not limited by these terms. In addition, these terms should not be construed as limiting the number of components unless a specific limitation on the quantity of components is expressed in singular or plural numbers.

Various embodiments of the present disclosure are directed to a semiconductor memory device capable of controlling a threshold voltage of a source select transistor and a manufacturing method thereof.

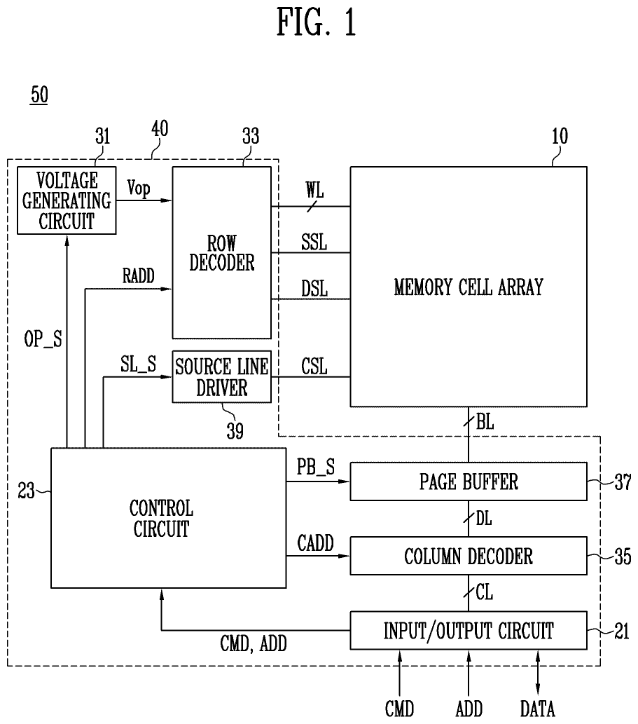

FIG. 1 is a block diagram illustrating a semiconductor memory device according to an embodiment of the present disclosure.

Referring to FIG. 1, a semiconductor memory device 50 includes a peripheral circuit 40 and a memory cell array 10.

The peripheral circuit 40, for example, performs a program operation of storing data in the memory cell array 10, a read operation of outputting data stored in the memory cell array 10, and an erase operation of erasing data stored in the memory cell array 10. In this embodiment, the peripheral circuit 40 includes an input/output circuit 21, a control circuit 23, a voltage generating circuit 31, a row decoder 33, a column decoder 35, a page buffer 37, and a source line driver 39.

The peripheral circuit 40 is coupled to the memory cell array 10 through a common source line CSL, bit lines BL, a drain select line DSL, word lines WL, and a source select line SSL.

The input/output circuit 21 transfers a command CMD and an address ADD, received from an external device (for example, a memory controller) of the semiconductor memory device 50, to the control circuit 23. The input/output circuit 21 exchanges data DATA with the external device and the column decoder 35.

The control circuit 23 outputs an operation signal OP_S, a row address RADD, a source line control signal SL_S, a page buffer control signal PB_S, and a column address CADD in response to receiving the command CMD and the address ADD.

The voltage generating circuit 31 generates various operating voltages Vop that are used for a program operation, a read operation, and an erase operation in response to receiving the operation signal OP_S.

The row decoder 33 delivers the operating voltages Vop to the drain select line DSL, the word lines WL, and the source select line SSL in response to receiving the row address RADD.

The column decoder 35 transmits the data DATA, input from the input/output circuit 21, to the page buffer 37 or transmits data DATA, stored in the page buffer 37 to the input/output circuit 21 in response to receiving the column address CADD. The column decoder 35 exchanges data DATA with the input/output circuit 21 through column lines CL. The column decoder 35 exchanges data DATA with the page buffer 37 through data lines DL.

The page buffer 37 stores read data, received through the bit lines BL, in response to receiving the page buffer control signal PB_S. The page buffer 37 senses the voltages or currents of the bit lines BL during a read operation.

The source line driver 39 controls a voltage applied to the common source line CSL in response to receiving the source line control signal SL_S.

The memory cell array 10 includes a plurality of memory blocks. Each of the memory blocks includes a plurality of memory cells arranged in a three-dimensional (3D) form. Each memory cell may be a nonvolatile memory cell. In an embodiment, each memory cell may be a NAND flash memory cell.

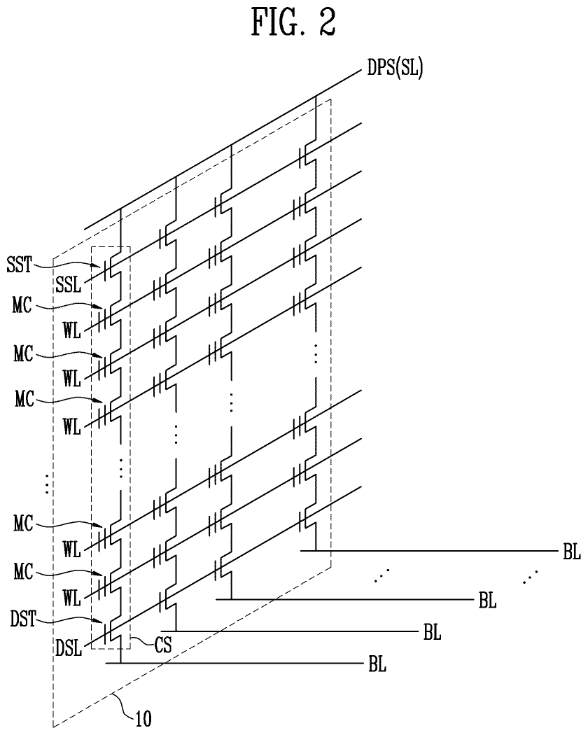

FIG. 2 is a circuit diagram illustrating a memory cell array according to an embodiment of the present disclosure.

Referring to FIG. 2, the memory cell array 10 includes a plurality of memory cell strings CS. The plurality of memory cell strings CS is coupled to a plurality of bit lines BL and a doped semiconductor layer DPS that is provided as a source layer SL. The common source line CSL illustrated in FIG. 1 is coupled to the plurality of cell strings CS via the doped semiconductor layer DPS.

Each memory cell string CS includes a source select transistor SST, a plurality of memory cells MC, and a drain select transistor DST. The memory cells MC are connected in series between the source select transistor SST and the drain select transistor DST. The source select transistor SST controls an electrical connection or relationship between the plurality of memory cells MC and the doped semiconductor layer DPS. The drain select transistor DST controls an electrical connection or relationship between the plurality of memory cells MC and the corresponding bit line BL.

The plurality of word lines WL provide a plurality of signals to a plurality of gates of the plurality of memory cells MC. In an embodiment, a section of each word line WL may serve as the gate of each memory cell MC. A source select line SSL provides a signal to a gate electrode of the source select transistor SST. In an embodiment, a section of the source select line SSL may serve as the gate electrode of the source select transistor SST. A drain select line DSL provides a signal to a gate electrode of the drain select transistor DST. In an embodiment, a section of the drain select line DSL may serve as the gate electrode of the source select transistor SST.

An operating voltage that precharges the channel layer of the corresponding memory cell string CS may be applied to each bit line BL. An operating voltage for discharging the channel potential of the memory cell string CS may be applied to the doped semiconductor layer DPS.

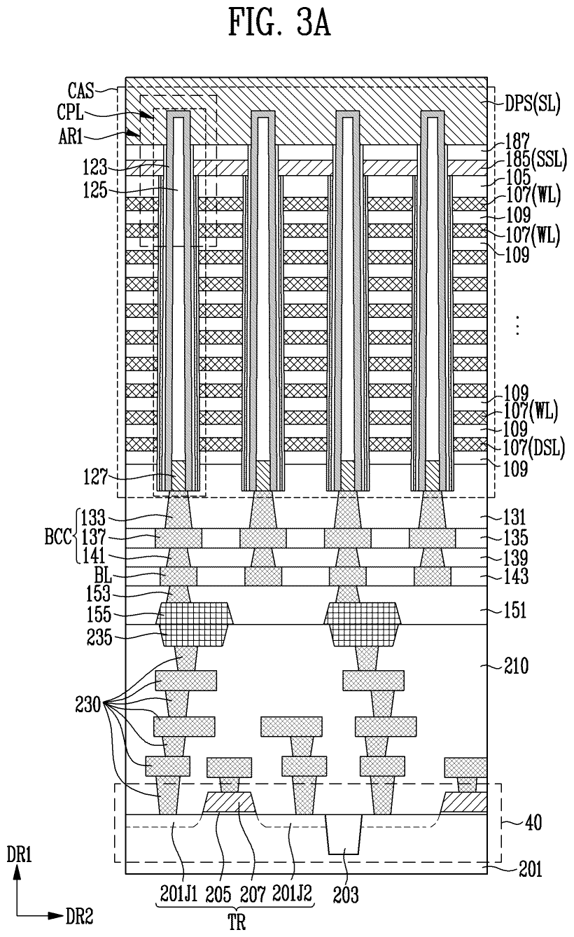

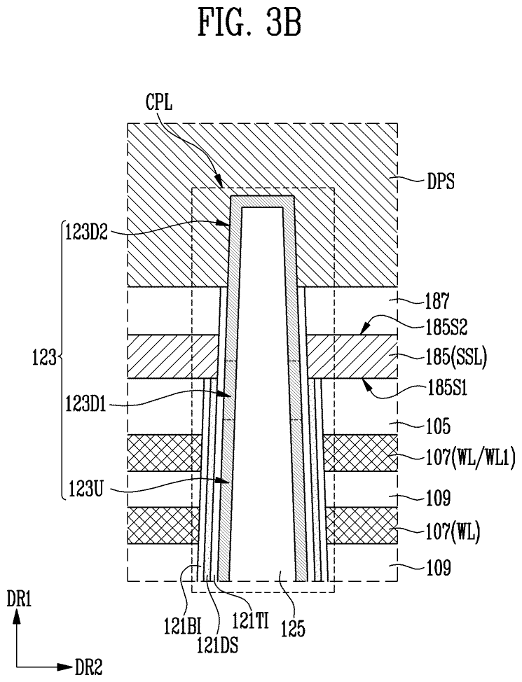

FIG. 3A and FIG. 3B are sectional views illustrating the semiconductor memory device according to an embodiment of the present disclosure. The cross-hatching throughout the figures illustrates corresponding or similar areas between the figures rather than indicating the materials for the areas.

FIG. 3B is an enlarged sectional view of an “AR1” area illustrated in FIG. 3A.

Referring to FIG. 3A and FIG. 3B, a semiconductor memory device includes a cell array structure CAS, a doped semiconductor layer DPS, a bit line BL, a peripheral circuit structure 40, and an interconnection structure for electrical connection between the peripheral circuit structure 40 and the cell array structure CAS.

The cell array structure CAS includes a plurality of memory cells arranged in three dimensions. In an embodiment, the plurality of memory cells is included in the plurality of memory cell strings CS described with reference to FIG. 2. Each memory cell string CS is coupled to a plurality of conductive layers 107 and 185. The plurality of conductive layers 107 and 185 includes the plurality of first conductive layers 107 used as the drain select line DSL and the plurality of word lines WL and the second conductive layer 185 used as the source select line SSL.

The plurality of first conductive layers 107 is stacked over or on the semiconductor substrate 61 while being spaced apart in a first direction DR1. The second conductive layer 185 is spaced apart from the plurality of first conductive layers 107 in the first direction DR1. The plurality of first conductive layers 107 and the second conductive layer 185 each extends along a plane perpendicular to an axis oriented in the first direction DR1. In an embodiment, each of the plurality of first conductive layers 107 and the second conductive layer 185 extends in the second direction DR2 along the plane perpendicular to the axis oriented in the first direction DR1.

The plurality of first conductive layers 107 and the second conductive layer 185 each includes at least one of a doped semiconductor layer and a metal layer in an embodiment. The doped semiconductor layer for each of the plurality of first conductive layers 107 and the second conductive layer 185 may include a doped silicon layer. The metal layer for each of the plurality of first conductive layers 107 and the second conductive layer 185 may include tungsten, copper, molybdenum, and so forth. The plurality of first conductive layers 107 and the second conductive layer 185 each may further include a metal nitride layer. The metal nitride layer may include titanium nitride, tantalum nitride, and so forth. The metal nitride layer may extend along a surface of the metal layer.

The second conductive layer 185 may include a conductive material different from those of the plurality of first conductive layers 107. In an embodiment, each of the plurality of first conductive layers 107 includes a metal layer and a metal nitride layer, and the second conductive layer 185 includes a doped silicon layer.

A first interlayer insulating layer 105 is interposed or located between the plurality of first conductive layers 107 and the second conductive layer 185 in this embodiment. The plurality of first conductive layers 107 and the plurality of second interlayer insulating layers 109 are alternately arranged in the first direction DR1. Thus, one of the plurality of second interlayer insulating layers 109 is disposed between two consecutive first conductive layers in the first direction DR1 among the plurality of first conductive layers 107.

The doped semiconductor layer DPS provided as the source layer SL is spaced apart from the second conductive layer 185 in the first direction DR1. A third interlayer insulating layer 187 is disposed between the second conductive layer 185 and the doped semiconductor layer DPS.

The first interlayer insulating layer 105, the plurality of second interlayer insulating layers 109, and the third interlayer insulating layer 187 may each include a silicon oxide layer or the like.

Each memory cell string CS includes a cell plug CPL. The cell plug CPL includes a channel layer 123, a tunnel insulating layer 121TI, a data storage layer 121DS, and a blocking insulating layer 121BI.

The channel layer 123 extends in the first direction DR1. The channel layer 123 forms a channel area of the memory cell string CS. The channel layer 123 may be formed of a semiconductor material. In an embodiment, the channel layer 123 includes silicon, germanium, or a mixture thereof.

The plurality of first conductive layers 107 and the second conductive layer 185 are stacked surrounding sections or portions of the side wall of each channel layer 123 and are spaced apart in the first direction DR1 along the side wall of the channel layer 123. The side wall of the channel layer 123 includes, for example, the angled structure that extends primarily in the first direction DR1. The stack including the plurality of first conductive layers 107, the plurality of second interlayer insulating layers 109, the first interlayer insulating layer 105, and the second conductive layer 185 extends to enclose the side wall of the channel layer 123. In an embodiment, the second conductive layer 185 is spaced apart from the side wall of the channel layer 123 in the second direction DR2.

The data storage layer 121DS extends in the first direction DR1 and is interposed between the stack including the plurality of first conductive layers 107 and the channel layer 123. The blocking insulating layer 121BI extends in the first direction DR1 and is interposed between the stack including the plurality of first conductive layers 107 and the data storage layer 121DS. The tunnel insulating layer 121TI is interposed between the data storage layer 121DS and the channel layer 123. The tunnel insulating layer 121TI extends in the first direction DR1 beyond the data storage layer 121DS and the blocking insulating layer 121BI such that the tunnel insulating layer 121TI is interposed between the second conductive layer 185 and the channel layer 123 in this example. The tunnel insulating layer 121TI extends in the first direction DR1 beyond the second conductive layer 185 and is interposed between the third interlayer insulating layer 187 and the channel layer 123 in this example.

The data storage layer 121DS may be used as a data storage area at a level or plane where the first conductive layer 107 for the word line WL is disposed. The data storage layer 121DS may be formed as a material layer that stores changed data, for example, using Fowler-Nordheim tunneling. In an embodiment, the data storage layer 121DS may be formed as a charge trap insulating layer or an insulating layer containing conductive nanodots. The charge trap insulating layer may include a silicon nitride layer. The tunnel insulating layer 121TI may include an insulating material capable of tunneling electrical charge. In an embodiment, the tunnel insulating layer 121TI may include a silicon oxide layer. The blocking insulating layer 121BI may include an insulating material capable of blocking electrical charge. In an embodiment, the blocking insulating layer 121BI may include an insulating layer having a dielectric constant higher than the dielectric constant of the tunnel insulating layer 121TI.

The cell plug CPL further includes a core insulating layer 125 and a capping pattern 127. The core insulating layer 125 and the capping pattern 127 are disposed in a central area of the cell plug CPL. The channel layer 123 extends along the side wall of the core insulating layer 125 and the side wall of the capping pattern 127. The capping pattern 127 may be used as a drain junction of the memory cell string CS. The capping pattern 127 may include at least one of an n-type impurity and a p-type impurity. In an embodiment, the capping pattern 127 includes the n-type impurity as a majority carrier.

The threshold voltage of the drain select transistor coupled to the drain select line DSL may be designed in various ways by controlling an impurity present in the capping pattern 127 and an impurity present in the channel layer 123 adjacent to the capping pattern 127.

A bit line BL is coupled to each capping pattern 127. The bit line BL may be disposed at a position spaced apart from the semiconductor substrate 201 in the first direction DR1. In an embodiment, the bit line BL is disposed between the semiconductor substrate 201 and the cell plug CPL.

The bit line BL is coupled to the capping pattern 127 via a bit line connection structure BCC. In an embodiment, the bit line connection structure BCC includes a conductive bit contact plug 133, a conductive pad pattern 137, and a conductive via structure 141. The conductive bit contact plug 133 is disposed in the first insulating structure 131 and is coupled to the capping pattern 127. The first insulating structure 131 is disposed at a level between the stack including the plurality of first conductive layers 107 and the plurality of second interlayer insulating layers 109 and the bit line BL. The first insulating structure 131 encloses a first end of the cell plug CPL closest to the bit line BL, in this example, the end of the cell plug CPL including the capping pattern 127. The conductive pad pattern 137 is disposed in the second insulating structure 135 and is coupled to the conductive bit contact plug 133. The second insulating structure 135 is disposed at a level between the first insulating structure 131 and the bit line BL. The conductive via structure 141 is disposed in the third insulating structure 139 and is coupled to the conductive pad pattern 137. The third insulating structure 139 is disposed at a level between the second insulating structure 135 and the bit line BL. The bit line BL is disposed in a bit line level insulating layer 143. The bit line level insulating layer 143 overlaps the second insulating structure 135 in the first direction DR1, where the third insulating structure 139 is interposed between the bit line level insulating layer 143 and the second insulating structure 135.

The connections between the bit line BL and the capping pattern 127 are not limited to the above-described embodiment. Although not illustrated in the drawings, according to an embodiment, the bit line BL may be directly connected to the capping pattern 127.

The cell array structure CAS is coupled to the peripheral circuit structure 40 via the interconnection structure that may be designed in various ways. In an embodiment, the interconnection structure includes a first conductive connection structure 153, a first conductive bonding structure 155, a second conductive bonding structure 235, and a second conductive connection structure 230.

The first conductive connection structure 153 and the first conductive bonding structure 155 are disposed in a fourth insulating structure 151. The fourth insulating structure 151 is disposed at a level between the bit line BL and the peripheral circuit structure 40. The first conductive connection structure 153 is shown disposed closer to the cell array structure CAS than to the first conductive bonding structure 155. The first conductive bonding structure 155 is shown disposed closer to the peripheral circuit structure 40 than to the first conductive connection structure 153 and is connected to the cell array structure CAS via the first conductive connection structure 153. In an embodiment, the first conductive connection structure 153 is connected to the bit line BL. According to an embodiment, the first conductive bonding structure 155 is electrically connected to the bit line BL via the first conductive connection structure 153, and is thereby connected to the cell array structure CAS.

A fifth insulating structure 210 is disposed between the peripheral circuit structure 40 and the fourth insulating structure 151. The first insulating structure 131, the second insulating structure 135, the third insulating structure 139, the fourth insulating structure 151, and the fifth insulating structure 210 may each include a single insulating layer or multiple insulating layers comprising two or more layers stacked in the first direction DR1.

The second conductive connection structure 230 and the second conductive bonding structure 235 are disposed in the fifth insulating structure 210. The second conductive connection structure 230 is disposed between the peripheral circuit structure 40 and the second conductive bonding structure 235. The second conductive bonding structure 235 is coupled to the peripheral circuit structure 40 via the second conductive connection structure 230.

The first conductive bonding structure 155 and the second conductive bonding structure 235 may each include metal such as copper. The first conductive bonding structure 155 and the second conductive bonding structure 235 may be bonded to each other.

The second conductive connection structure 230 includes multi-layered conductive patterns designed including various structures for electrical connection between the second conductive bonding structure 235 and the peripheral circuit structure 40. In an embodiment, the peripheral circuit structure 40 includes a transistor TR of a page buffer 37 illustrated in FIG. 1. The transistor TR is disposed in an active area of the semiconductor substrate 201 partitioned by an isolation layer 203. The transistor TR includes a first junction area 201J1 and a second junction area 201J2 formed in an active area of the semiconductor substrate 201 and a gate insulating layer 205 and a gate electrode 207 stacked over the active area of the semiconductor substrate 201 between the first junction area 201J1 and the second junction area 201J2. The first junction area 201J1 and the second junction area 201J2 are used as a source junction and a drain junction of the transistor TR. The first junction area 201J1 and the second junction area 201J2 include at least one of the n-type impurity and the p-type impurity. In an embodiment, when the transistor TR is provided as a N-channel metal oxide semiconductor (NMOS) transistor, the first junction area 201J1 and the second junction area 201J2 include the n-type impurity as the majority carrier.

The second conductive connection structure 230 connects the transistor TR to the cell array structure CAS via the first conductive bonding structure 155 and the second conductive bonding structure 235. In an embodiment, the second conductive connection structure 230 is electrically connected to the first junction area 201J1 of the transistor TR and is electrically connected to the bit line BL via the first conductive bonding structure 155 and the second conductive bonding structure 235. Thus, the transistor TR is electrically connected to the channel layer 123 of the memory cell array structure CAS via the bit line BL and the capping pattern 127.

The above-described cell array structure CAS, bit line BL, and first conductive connection structure 153, first conductive bonding structure 155, second conductive bonding structure 235, and second conductive connection structure 230 of the interconnection structure are disposed between the doped semiconductor layer DPS and the peripheral circuit structure 40. The cell plug CPL of the cell array structure CAS includes a second end contacting the doped semiconductor layer DPS in addition to the first end closest to the bit line BL. The second end of the cell plug CPL corresponds to the end of the channel layer 123 contacting the doped semiconductor layer DPS. The doped semiconductor layer DPS may include one or more grooves or slots into which the end of the channel layers 123 are inserted.

Referring to FIG. 3B, the channel layer 123 includes a first area 123U, a second area 123D1, and a third area 123D2. The first area 123U is a section or portion of the channel layer 123 disposed within or surrounded by the plurality of first conductive layers 107 provided as the plurality of word lines WL. The first area 123U may be an undoped area. The plurality of word lines WL is stacked along the side wall of the first area 123U and spaced apart from each other. The second area 123D1 is a section or portion of the channel layer 123 extending from the first area 123U in the first direction DR1, and at least a part of the second area 123D1 is disposed within or surrounded by at least section of the second conductive layer 185 provided as the source select line SSL. The second area 123D1 is a first doped area containing an impurity of a first conductivity type (hereinafter, referred to as a “first conductive impurity”) and an impurity of a second conductivity type (hereinafter, referred to as a “second conductive impurity”) opposite to the impurity of the first conductivity type. The first conductive impurity may be the p-type impurity, while the second conductive impurity may be the n-type impurity. In an embodiment, the second area 123D1 contains any of boron (B), phosphorus (P), and arsenic (As). The third area 123D2 is a section or portion of the channel layer 123 extending from the second area 123D1 in the first direction DR1 and includes an end of the channel layer 123 contacting the doped semiconductor layer DPS. The third area 123D2 may be a second doped area. The third area 123D2 may contain the conductive impurity at a concentration different from that of the second area 123D1. The second area 123D1 may contain a higher concentration of the p-type impurity than the third area 123D2 to have a higher threshold voltage than the third area 123D2. The concentration of the n-type impurity and the concentration of the p-type impurity in the second area 123D1 may vary depending on the threshold-voltage design condition of the source select transistor coupled to the second conductive layer 185. The third area 123D2 and the doped semiconductor layer DPS may include the n-type impurity as the majority carrier.

The threshold voltage characteristics of the source select transistor coupled to the second conductive layer 185 may be improved or secured when the second area 123D1 has a higher threshold voltage than the threshold voltage of the third area 123D2.

The second conductive layer 185 has a first surface 185S1 and a second surface 185S2 disposed on opposite sides of the second conductive layer 185 or facing in opposite directions. The first surface 185S1 faces the plurality of first conductive layers 107, while the second surface 185S2 faces the doped semiconductor layer DPS.

The plurality of word lines WL includes a first word line WL1 adjacent to the first interlayer insulating layer 105 that is adjacent to the second conductive layer 185, where the first word line WL1 is the closest conductive layer 107 to the second conductive layer 185. A boundary between the first area 123U and the second area 123D1 in the channel layer 123 is located at a level between the first word line WL1 and the first surface 185S1 of the second conductive layer 185 in this example. In an embodiment, the boundary between the first area 123U and the second area 123D1 may be located at any level where the first interlayer insulating layer 105 is disposed. A boundary between the second area 123D1 and the third area 123D2 in the channel layer 123 is located at a level between the first surface 185S1 and the second surface 185S2 of the second conductive layer 185, in other words, at any level where the second conductive layer 185 is disposed. Thus, a section or portion of the second conductive layer 185 surrounds, in the section direction DR2, a section of the second area 123D1 in the channel layer 123, and another section or portion of the second conductive layer 185 surrounds, in the section direction DR2, a section of the third area 123D2 in the channel layer 123.

Because a section or portion of the second conductive layer 185 surrounds a section of the third area 123D2 and overlaps a section or portion of the third area 123D2, a gate induced drain leakage (GIDL) current may be generated during the erase operation of the memory cell string CS illustrated in FIG. 3A.

The data storage layer 121DS of the cell plug CPL extends in the first direction DR1 and is interposed between the plurality of first conductive layers 107 and the side wall of the first area 123U in the channel layer 123. The data storage layer 121DS is cut off by or terminates at the second conductive layer 185 and does not extend between the second conductive layer 185 and the channel layer 123. In an embodiment, the data storage layer 121DS contacts the first surface 185S1 of the second conductive layer 185. Because the data storage layer 121DS of the cell plug CPL does not extend between the second conductive layer 185 and the channel layer 123, the operation of separately programming or erasing the source select transistor, which is performed to control the threshold voltage of the source select transistor coupled to the second conductive layer 185, need not be performed.

The blocking insulating layer 121BI of the cell plug CPL extends in the first direction DR1 and is interposed between the stack including the plurality of first conductive layers 107 and the data storage layer 121DS. Similar to the data storage layer 121DS, the blocking insulating layer 121BI contacts the first surface 185S1 of the second conductive layer 185 in an embodiment.

The tunnel insulating layer 121TI of the cell plug CPL extends in the first direction DR1 and is interposed between the data storage layer 121DS and at least the first area 123U of the channel layer 123. The tunnel insulating layer 121TI extends beyond the data storage layer 121DS and the blocking insulating layer 121BI in the first direction DR1 and is interposed between the second conductive layer 185 and the channel layer 123 in this example. The tunnel insulating layer 121TI extends beyond the second surface 185S2 of the second conductive layer 185 in the first direction DR1 and is interposed between the third interlayer insulating layer 187 and the channel layer 123.

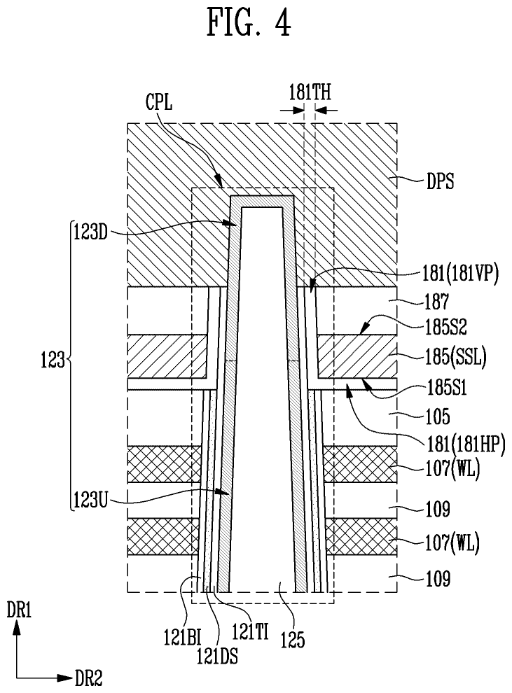

FIG. 4 is a sectional view illustrating the semiconductor memory device according to an embodiment of the present disclosure.

FIG. 4 is an enlarged sectional view illustrating an area of the semiconductor memory device corresponding to the “AR1” area illustrated in FIG. 3A. Descriptions of the same or similar elements of FIG. 4 as in the embodiment illustrated in FIG. 3A and FIG. 3B are provided above.

Referring to FIG. 4, the channel layer 123 includes an undoped area 123U and a doped area 123D. The undoped area 123U is a section or portion of the channel layer 123 disposed within or surrounded by the plurality of first conductive layers 107 provided as the plurality of word lines WL. Each of the plurality of word lines WL is stacked along the side wall of the undoped area 123U and is spaced apart from each other. The doped area 123D is a portion of the channel layer 123 including the end of the channel area 123 contacting the doped semiconductor layer DPS. The doped area 123D may be distributed from the end of the channel layer 123 toward the undoped area 123U. The undoped area 123U may have a threshold voltage higher than the threshold voltage of the doped area 123D. The doped area 123D and the doped semiconductor layer DPS may include the n-type impurity as the majority carrier.

As described above with reference to FIG. 3B, the second conductive layer 185 provided as the source select line SSL has a first surface 185S1 and a second surface 185S2.

The boundary between the undoped area 123U and the doped area 123D in the channel layer 123 is located at a level between the first surface 185S1 and the second surface 18552 of the second conductive layer 185 in this example. Thus, a section or portion of the second conductive layer 185 surrounds a section of the undoped area 123U in the channel layer 123, while another section or portion of the second conductive layer 185 surrounds a section of the doped area 123D in the channel layer 123. Because at least a section or portion of the second conductive layer 185 surrounds or overlaps a section or portion of the doped area 123D, the GIDL current may be generated during the erase operation of the memory cell string.

The semiconductor memory device includes a gate insulating layer 181 as shown in the embodiment of FIG. 4. The gate insulating layer 181 includes a first member, referred to as a vertical portion 181VP, and a second member, referred to as a horizontal portion 181HP. The vertical portion 181VP is interposed between the second conductive layer 185 and the channel layer 123 and extends primarily in the first direction DR1. The horizontal portion 181HP extends from the vertical portion 181VP along the first surface 185S1 of the second conductive layer 185 and extends primarily in the second direction DR2. The vertical portion 181VP and the horizontal portion 181HP may be formed as a single continuous structure. The threshold voltage of the source select transistor coupled to the second conductive layer 185 may be designed in various ways by controlling a thickness 181TH of the vertical portion 181VP in a direction (for example, the second direction DR2) that extends away from the channel layer 123. As the thickness 181TH of the vertical portion 181VP increases, the threshold voltage of the source select transistor increases. According to an embodiment, in the direction (for example, the second direction DR2) away from the side wall of the channel layer 123, the vertical portion 181VP may be formed with a thickness greater than a thickness of each of the tunnel insulating layer 121TI, the data storage layer 121DS, and the blocking insulating layer 121BI. The terms “vertical” and “horizontal” indicate a relative positional relationships utilized for the convenience of description and do not otherwise limit the embodiments of the present disclosure.

As described above, the source select transistor as coupled to the second conductive layer 185 may improve or secure threshold voltage characteristics by controlling or adjusting the thickness of the gate insulating layer 181, which is distinct from the cell plug CPL.

The data storage layer 121DS of the cell plug CPL extends in the first direction DR1 and is interposed between the plurality of first conductive layers 107 and the side wall of the channel layer 123. The data storage layer 121DS is cut off by or terminates at the gate insulating layer 181 and does not extend between the second conductive layer 185 and the channel layer 123. Because the data storage layer 121DS of the cell plug CPL does not extend between the second conductive layer 185 and the channel layer 123, the operation of separately programming or erasing the source select transistor, which is performed to control the threshold voltage of the source select transistor coupled to the second conductive layer 185, need not be performed. The data storage layer 121DS extends in the same direction as the vertical portion 181VP of the gate insulating layer 181 that is thicker than the data storage layer 121DS in the second direction D2. The gate insulating layer 181 is disposed on a surface or end of the data storage layer 121DS closest to the second conductive layer 185. The vertical portion 181VP of the gate insulating layer 181 is aligned with the data storage layer 121DS in the first direction DR1.

The blocking insulating layer 121BI of the cell plug CPL extends in the first direction DR1 and is interposed between the plurality of first conductive layers 107 and the data storage layer 121DS. Similar to the data storage layer 121DS, the blocking insulating layer 121BI is cut off by or terminates at the gate insulating layer 181. The blocking insulating layer 121BI extends in the same direction as the vertical portion 181VP of the gate insulating layer 181 that is thicker than the blocking insulating layer 121BI in the second direction D2. The gate insulating layer 181 is disposed on a surface or end of the blocking insulating layer 121BI closest to the second conductive layer 185. The vertical portion 181VP of the gate insulating layer 181 is aligned with the blocking insulating layer 121BI in the first direction DR1.

The data storage layer 121DS and the blocking insulating layer 121BI of the cell plug CPL are interposed not only between the channel layer 123 and the first interlayer insulating layer 105, but also between the channel layer 123 and the plurality of second interlayer insulating layers 109. The horizontal portion 181HP of the gate insulating layer 181 is interposed between the second conductive layer 185 and the first interlayer insulating layer 105 in the embodiment of FIG. 4. The vertical portion 181VP of the gate insulating layer 181 extends in the first direction DR1 and is interposed between the channel layer 123 and the third interlayer insulating layer 187.

The tunnel insulating layer 121TI of the cell plug CPL is interposed between the side wall of the channel layer 123 and the data storage layer 121DS. The tunnel insulating layer 121TI extends beyond the data storage layer 121DS and the blocking insulating layer 121BI in the first direction DR1 such that the tunnel insulating layer 121TI is interposed between the vertical portion 181VP of the gate insulating layer 181 and the channel layer 123. The tunnel insulating layer 121TI extends beyond the second surface 185S2 of the second conductive layer 185 in the first direction DR1 and is interposed between the third interlayer insulating layer 187 and the channel layer 123. The tunnel insulating layer 121TI, the data storage layer 121DS, and the blocking insulating layer 121BI are parallel to each other and to the side wall of the channel layer 123 as shown in the embodiments of the drawings, and generally extend at an angle with respect to the first direction DR1, resulting in a tapered shape for the cell plug CPL.

Referring to FIG. 3B and FIG. 4, the channel layer 123 of the cell plug CPL extends in the first direction DR1 beyond the third interlayer insulating layer 187 and into the doped semiconductor layer DPS that surrounds or encloses the end of the channel layer 123. The channel layer 123 of the cell plug CPL encloses the end of the core insulating layer 125 and prevents contact between the doped semiconductor layer DPS and the core insulating layer 125, thereby isolating the core insulating layer 125 from the doped semiconductor layer DPS.

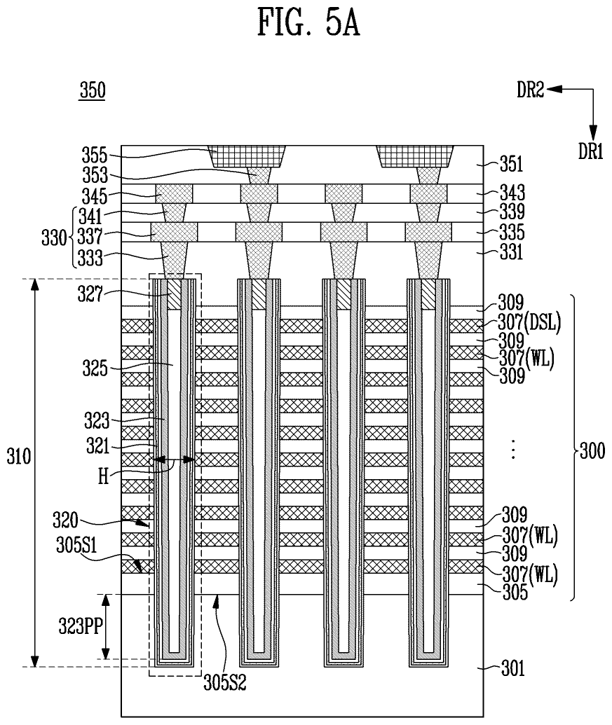

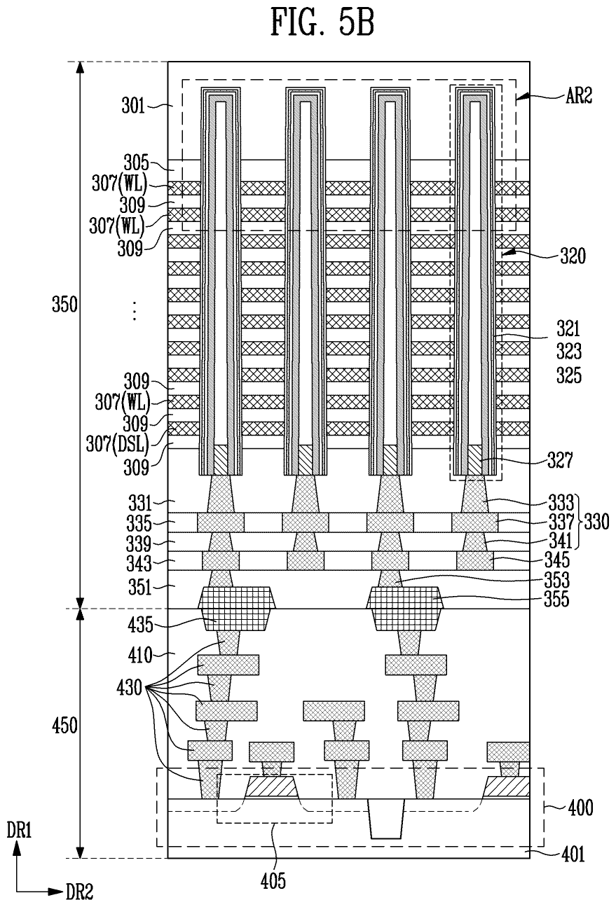

FIG. 5A is a sectional view of a semiconductor memory device during the formation of a first structure.

Referring to FIG. 5A, a cell array structure 310 is formed over a sacrificial substrate 301. The sacrificial substrate 301 may contain silicon.

Forming the cell array structure 310 includes forming a stacked body 300 over or on the sacrificial substrate 301 and forming the cell plugs 320. Each cell plug 320 extends through the stacked body 300 and includes a protrusion that extends beyond the stacked body 300 and into the sacrificial substrate 301.

Forming the stacked body 300 includes forming a first interlayer insulating layer 305 over or on the sacrificial substrate 301 and alternately stacking a plurality of first material layers with a plurality of second material layers over or on the first interlayer insulating layer 305. In an embodiment, the plurality of first material layers may be a plurality of first conductive layers 307, and the plurality of second material layers may be a plurality of second interlayer insulating layers 309. An embodiments of the present disclosure are not limited to this example. In one embodiment, each of the plurality of first material layers is a sacrificial layer having a different etch rate with respect to the etch rate of the plurality of second material layers, and the plurality of second material layers is the plurality of second interlayer insulating layers 309 shown in FIG. 5A. When the first material layers are the first conductive layers 307 shown in FIG. 5A, the first material layers may be formed of the same conductive material as the first conductive layer 107 described with reference to FIG. 3A and FIG. 3B. When the first material layers function as sacrificial layers, the first material layers may include a silicon nitride layer. The first interlayer insulating layer 305 and the plurality of second interlayer insulating layers 309 each may include a silicon oxide layer.

The first interlayer insulating layer 305 has a first surface 305S1 and a second surface 305S2 disposed on opposite sides of the first interlayer insulating layer 305 or facing in opposite directions. The second surface 305S2 faces the sacrificial substrate 301. A direction in which the second surface 305S2 faces is referred to as the first direction DR1. The above-described plurality of first material layers is alternately stacked with the plurality of second material layers over or on the first surface 305S1 of the first interlayer insulating layer 305. In an embodiment, the plurality of first conductive layers 307 is alternately stacked with the plurality of second interlayer insulating layers 309 over the first surface 305S1 of the first interlayer insulating layer 305. The plurality of first conductive layers 307 may be used as the plurality of word lines WL and the drain select line DSL.

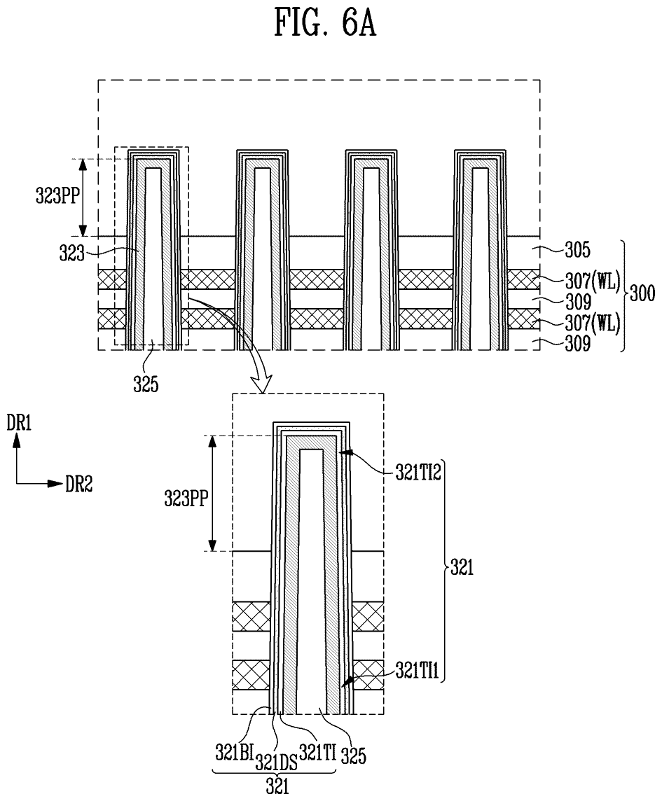

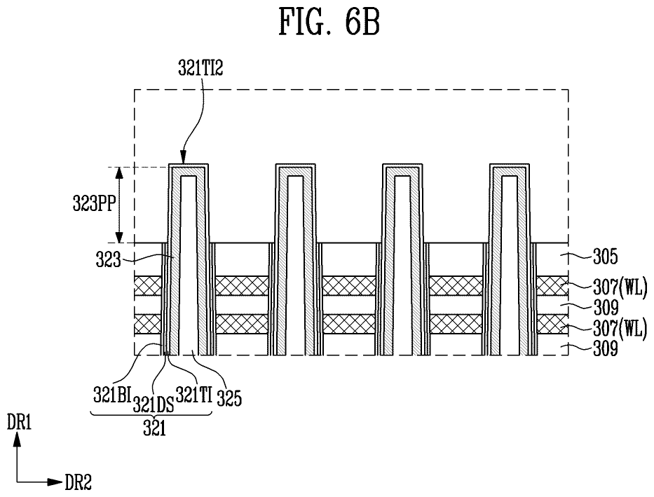

Forming the cell plugs 320 includes forming a mask pattern (not illustrated) over the stacked body 300, forming, utilizing an etching process, holes H through the stacked body 300 using the mask pattern as an etch barrier, forming a memory layer 321 in each hole H, and forming a channel layer 323 on each memory layer 321 inside the hole H. The hole H passes through the stacked body 300 and extends into the sacrificial substrate 301. Each memory layer 321 includes a blocking insulating layer 321BI, a data storage layer 321DS, and a tunnel insulating layer 321TI illustrated in FIG. 6A. The blocking insulating layer 321BI, the data storage layer 321DS, and the tunnel insulating layer 321TI illustrated in FIG. 6A may be formed of the same materials as the blocking insulating layer 121BI, the data storage layer 121DS, and the tunnel insulating layer 121TI, respectively, as described with reference to FIG. 3B.

Each channel layer 323 may be formed by depositing a liner semiconductor layer on each memory layer 321. In an embodiment, the holes H may not be completely filled with the channel layers 323, and the central area of each hole H may be opened when the channel layer 323 is formed. In this example, forming the cell plugs 320 further includes filling the central area of the holes H surrounded by each channel layer 323 with the core insulating layer 325, removing a portion of each core insulating layer 325 to form a recessed area, and filling the recessed areas with a capping pattern 327. The capping pattern 327 may be formed of a doped semiconductor layer. In an embodiment, the capping pattern 327 may include an n-type impurity as the majority carrier.

After forming the cell plugs 320, the mask pattern may be removed. Subsequently, the first insulating structure 331 is formed to cover the ends of the cell plugs 320 and the stacked body 300. One or more slits (not illustrated) may be formed through the first insulating structure 331 and the stacked body 300. The plurality of first conductive layers 307 of the stacked body 300 may be separated by the one or more slits into memory blocks or sub-blocks.

Although not illustrated in the drawings, when each of the plurality of first material layers of the stacked body 300 is formed as sacrificial layers, a process of replacing the sacrificial layers with the first conductive layers 307 through the one or more slits is performed.

As described above, the stacked body 300 includes the first interlayer insulating layer 305, the plurality of first conductive layers 307, and the plurality of second interlayer insulating layers 309. The cell plugs 320 extend through the stacked body 300 and protrude into the sacrificial substrate 301 and may be formed utilizing various methods. According to the above-described process, the channel layer 323 of each cell plug 320 includes a protrusion 323PP that extends in the first direction DR1 beyond the second surface 305S2 of the first interlayer insulating layer 305. Each memory layer 321 includes a first area interposed between the channel layer 323 and the stacked body 300 and a second area covering the protrusions 323PP of the channel layers 323.

Forming the first structure 350 includes forming the bit line connection structures 330 after forming the first insulating structure 331. In an embodiment, forming the bit line connection structures 330 includes forming the conductive bit contact plugs 333 in the first insulating structure 331, forming the second insulating structure 335 to cover the conductive bit contact plugs 333, forming the conductive pad patterns 337 in the second insulating structure 335, forming the third insulating structure 339 to cover the conductive pad patterns 337, and forming conductive via structures 341 in the third insulating structure 339. The conductive bit contact plug 333 extends through the first insulating structure 331 and is electrically coupled to the capping patterns 327. Each conductive pad pattern 337 extends through the second insulating structure 335 and is electrically coupled to one of the conductive bit contact plugs 333. The conductive via structures 341 extend through the third insulating structure 339 and are electrically coupled to the conductive pad patterns 337.

Forming the first structure 350 includes forming bit lines 345 after forming the bit line connection structures 330. In an embodiment, forming the bit lines 345 includes forming the bit line level insulating layer 343 to cover the conductive via structures 341, forming trenches or openings that extend through the bit line level insulating layer 343, and filling the trenches or openings with a conductive material. The conductive material filling the trenches or openings may be referred to as the bit lines 345, and each bit line 345 is electrically coupled to one of the conductive via structures 341 of the bit line connection structures 330.

Forming the first structure 350 further includes forming the first conductive connection structures 353 and the first conductive bonding structures 355 of the interconnection structure after forming the bit lines 345. The first conductive connection structures 353 and the first conductive bonding structures 355 are formed in the fourth insulating structure 351. The fourth insulating structure 351 is over the bit line level insulating layer 343. Each first conductive connection structure 353 contacts one of the bit lines 345 and extends into the fourth insulating structure 351. Each first conductive bonding structure 355 contacts one of the first conductive connection structures 353 and has a surface exposed to the outside of the fourth insulating structure 351.

FIG. 5B is a sectional view of a semiconductor memory device during a bonding process between the first structure and a second structure.

Referring to FIG. 5B, the second structure 450 may be formed using processes that are performed separately from the processes described with reference to FIG. 5A. The second structure 450 includes a peripheral circuit structure 400 including a plurality of transistors 405, second conductive connection structures 430 connected to the peripheral circuit structure 400, and second conductive bonding structures 435 connected to the second conductive connection structures 430. Description of the transistor 405, the second conductive connection structure 430, and the second conductive bonding structure 435 are described with reference to similar elements in FIG. 3A above.

The transistor 405 of the peripheral circuit structure 400 is formed in an active area of a semiconductor substrate 401. The semiconductor substrate 401 and the transistor 405 are covered with a fifth insulating structure 410. The second conductive connection structure 430s and the second conductive bonding structures 435 are disposed in the fifth insulating structure 410. The second conductive bonding structures 435 each have a surface exposed the outside of the fifth insulating structure 410.

The first structure 350 and the second structure 450 are aligned such that the first conductive bonding structures 355 of the first structure 350 are aligned with the second conductive bonding structures 435 of the second structure 450. Subsequently, the first conductive bonding structure 355 and the second conductive bonding structure 435 are bonded to each other to electrically connect the first structure 350 and the second structure 450.

Subsequent processes are described with reference to the following drawings and are focused on an enlarged area corresponding to the area AR2 illustrated in FIG. 5B.

FIG. 6A and FIG. 6B are sectional views of a semiconductor memory device during processes of exposing a portion of a tunnel insulating layer.

Referring to FIG. 6A, after the bonding process described with reference to FIG. 5B, the sacrificial substrate 301 illustrated in FIG. 5B is removed. Thus, the second area of the memory layer 321 covering the protrusion 323PP of the channel layer 323 is exposed.

The tunnel insulating layer 321TI of the memory layer 321 may include a first area 321TI1 and a second area 321TI2. The first area 321TI1 is a portion or section of the memory layer 321 disposed between the stacked body 300 and the channel layer 323, and the second area 231TI2 is a portion or section of the memory layer 321 covering the protrusion 323PP of the channel layer 323. The data storage layer 321DS of the memory layer 321 extends along the first area 321TI1 and the second area 321TI2 of the tunnel insulating layer 321TI. The blocking insulating layer 321BI of the memory layer 321 extends along the data storage layer 321DS, and the. data storage layer 321DS is disposed between the blocking insulating layer 321BI and the tunnel insulating layer 321TI. Because the sacrificial substrate 301 illustrated in FIG. 5B is removed, a portion or section of the blocking insulating layer 321BI extending along the data storage layer 321DS that is disposed on the second area 321TI2 of the tunnel insulating layer 321TI may be exposed.

Referring to FIG. 6B, after the exposed portion of the blocking insulating layer 321BI is selectively removed, a portion of the data storage layer 321DS covering the second area 321TI2 of the tunnel insulating layer 321TI is selectively removed. As a result, the second area 321TI2 of the tunnel insulating layer 321TI is exposed.

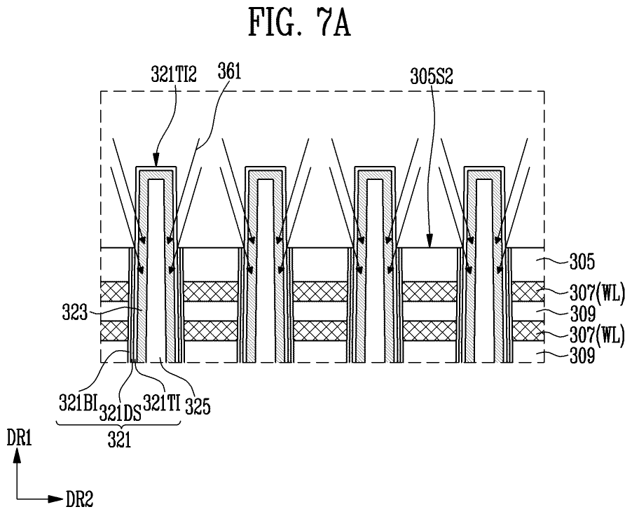

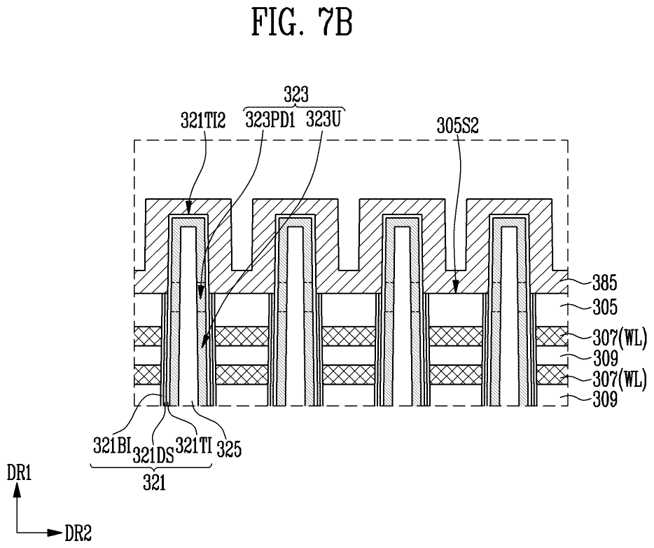

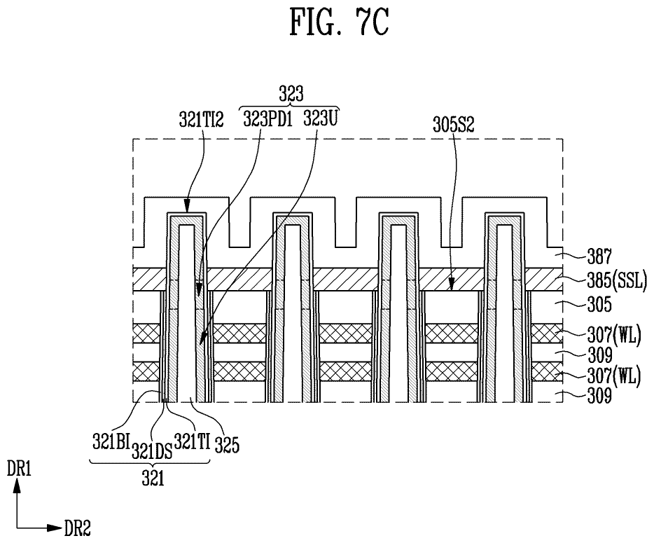

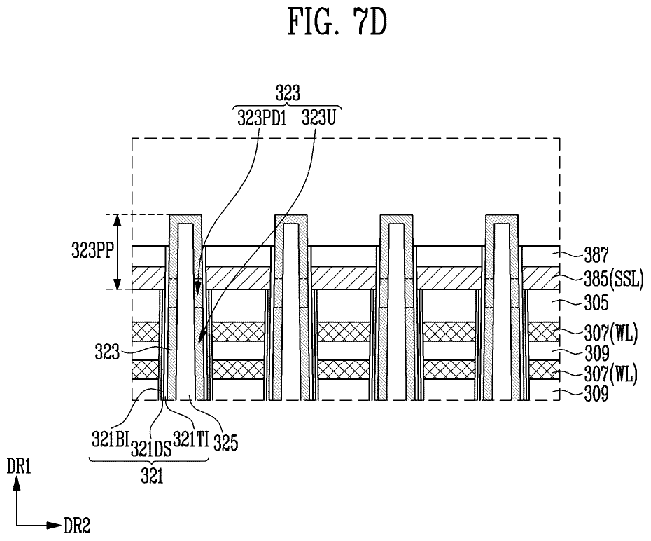

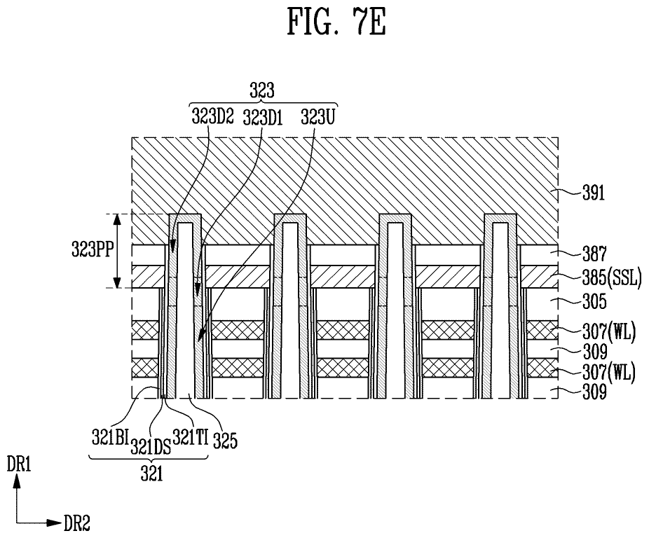

FIG. 7A through FIG. 7E are sectional views illustrating an embodiment of a semiconductor memory device during processes performed on the semiconductor memory device of FIG. 6B.

Referring to FIG. 7A, a first conductive impurity 361 is injected into a portion or area of the channel layer 323 closest to or surrounded by at least the second surface 305S2 of the first interlayer insulating layer 305 using, as a buffer layer, the second area 321TI2 of the tunnel insulating layer 321TI exposed by the process described with reference to FIG. 6B. The first conductive impurity 361 may be the p-type impurity.

Referring to FIG. 7B, a preliminary doped area 323PD1 is formed in a portion or area of the channel layer 323 into which the first conductive impurity 361 is injected as described with reference to FIG. 7A. Another portion or area of the channel layer 323 interposed between the plurality of first conductive layers 307 and the memory layer 321 may remain as an undoped area 323U.

Subsequently, a second conductive layer 385 is formed over the second surface 305S2 of the first interlayer insulating layer 305. The second conductive layer 385 is formed to cover at least part of the second area 321TI2 of the tunnel insulating layer 321TI. The second conductive layer 385 may be formed of the same conductive material as the second conductive layer 185 described with reference to FIG. 3A and FIG. 3B.

Referring to FIG. 7C, a portion of the second conductive layer 385 is removed to expose a part of the second area 321TI2 of the tunnel insulating layer 321TI, which part covers the resulting protrusions. The remaining second conductive layer 385 forms the source select line SSL over the second surface 305S2 of the first interlayer insulating layer 305.

As described above, because the data storage layer 321DS does not remain or is not present between the second conductive layer 385 and the channel layer 323, a phenomenon in which the threshold voltage of the source select transistor is changed due to charge stored in the data storage layer 321DS may be improved. The second area 321TI2 of the tunnel insulating layer 321TI may advantageously remain to be used as the gate insulating layer of the source select transistor.

Subsequently, a third interlayer insulating layer 387 is formed over the source select line SSL. The third interlayer insulating layer 387 is formed to cover at least part of the exposed second area 321TI2 of the tunnel insulating layer 321TI.

Referring to FIG. 7D, a portion of the third interlayer insulating layer 387 is removed to expose a part of the second area 321TI2 of the tunnel insulating layer 321TI. The third interlayer insulating layer 387 may remain to cover the source select line SSL. The end of the second area 321TI2 of the tunnel insulating layer 321TI may be removed during a process of removing a portion of the third interlayer insulating layer 387 or using a separate etching process. As a result, the end of the protrusion 323PP of the channel layer 323 extending beyond the third interlayer insulating layer 387 is exposed.

Referring to FIG. 7E, a second conductive impurity opposite to the first conductive impurity is doped into the protrusion 323PP of the channel layer 323 and the preliminary doped area 323PD1 illustrated in FIG. 7D.

In an embodiment, doping the second conductive impurity includes forming the doped semiconductor layer 391 over the third interlayer insulating layer 387 and contacting the exposed ends of the protrusions 323PP, and diffusing the impurity from the doped semiconductor layer 391 into the protrusion 323PP of the channel layer 323 and the preliminary doped area 323PD1 illustrated in FIG. 7D.

The doped semiconductor layer 391 includes the second conductive impurity. The second conductive impurity may be the n-type impurity. As the second conductive impurity diffuses from the doped semiconductor layer 391 into the preliminary doped area 323PD1 illustrated in FIG. 7D, the first doped area 323D1 and the second doped area 323D2 are formed in the channel layer 323.

As described above, when the first doped area 323D1 contains the p-type impurity at a concentration higher than the concentration of the second doped area 323D2, the first doped area 323D1 has a threshold voltage higher than the threshold voltage of the second doped area 323D2. Thus, improving or securing the threshold voltage characteristics of the source select transistor coupled to the source select line SSL is possible.

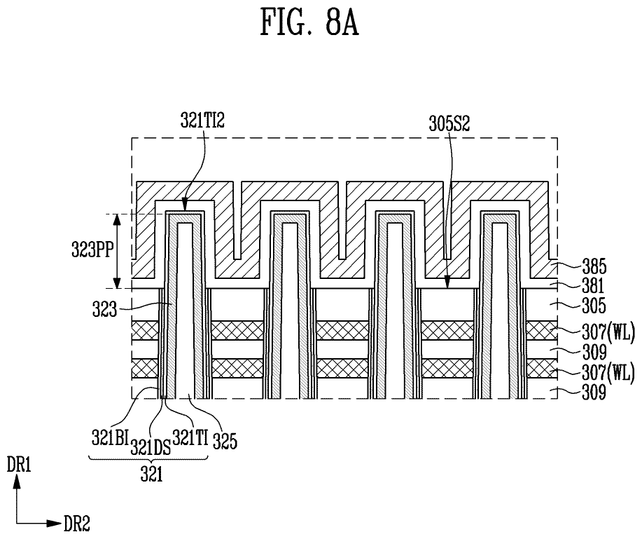

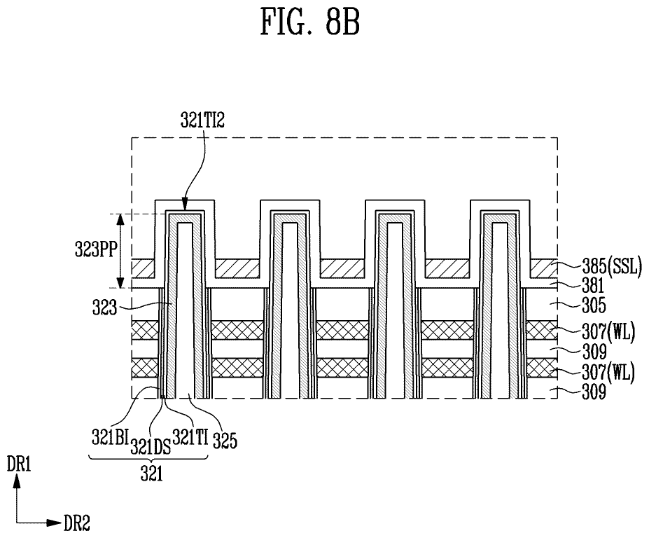

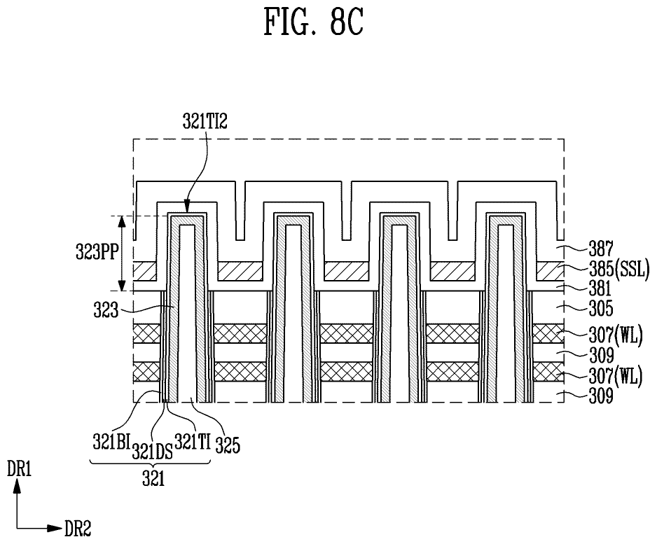

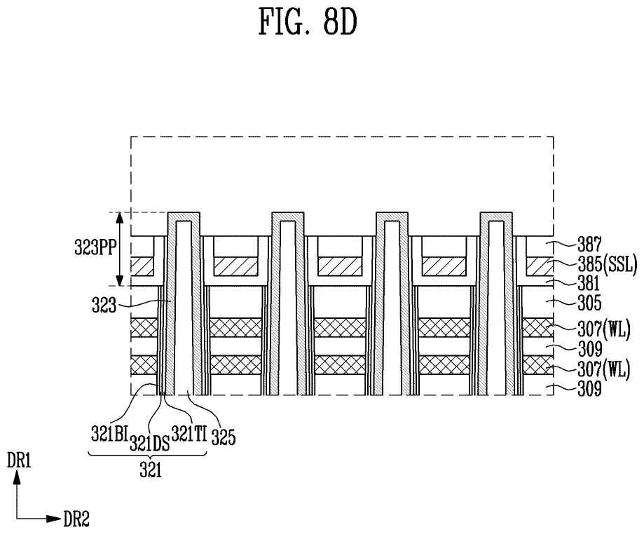

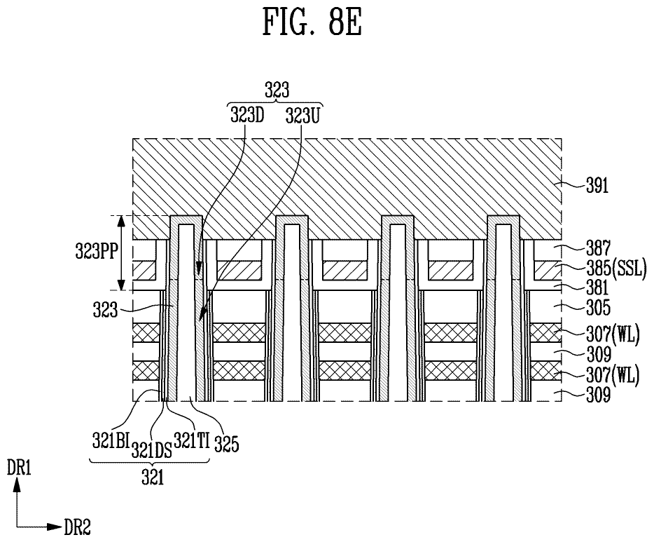

FIG. 8A through FIG. 8E are sectional views illustrating an embodiment of a semiconductor memory device during processes performed after the process applied to the semiconductor memory device of FIG. 6B. Descriptions of the configurations of FIG. 8A through FIG. 8E or processes similar or the same as the configuration described with reference to FIG. 7A through 7E are provided above.

Referring to FIG. 8A, the gate insulating layer 381 is formed over the second surface 305S2 of the first interlayer insulating layer 305 to cover the second area 321TI2 of the tunnel insulating layer 321TI exposed by the process described with reference to FIG. 6B.

Subsequently, the second conductive layer 385 is formed over the gate insulating layer 381. The second conductive layer 385 is formed over or on the surface of the gate insulating layer 381.

Referring to FIG. 8B, a portion of the second conductive layer 385 is removed to expose the gate insulating layer 381. The remaining second conductive layer 385 forms the source select line SSL over the gate insulating layer 381. While the gate insulating layer 381 is interposed between the source select line SSL and the protrusion 323PP of the channel layer 323, the source select line SSL may enclose a portion of the protrusion 323PP.

As described above, because the gate insulating layer 381 is additionally deposited after removing a portion of the data storage layer 321DS, the deposition thickness of the gate insulating layer 381 may be controlled or determined according to a selected or target threshold voltage of the source select transistor coupled to the source select line SSL. Thus, the threshold voltage of the source select transistor may be improved or secured to be higher than the initial threshold voltage of the memory cell coupled to the word line WL.

Referring to FIG. 8C, the third interlayer insulating layer 387 is formed over the source select line SSL. The third interlayer insulating layer 387 is formed to cover the exposed surface of the gate insulating layer 381.

Referring to FIG. 8D, in order to expose the end of the protrusion 323PP in the channel layer 323, a portion of the third interlayer insulating layer 387, a portion of the gate insulating layer 381, and a portion of the second area 321TI2 of the tunnel insulating layer 321TI illustrated in FIG. 8C are removed. The third interlayer insulating layer 387 remains to cover or isolate the source select line SSL.

Referring to FIG. 8E, a portion of the protrusion 322PP of the channel layer 323 is doped with the n-type impurity.

In an embodiment, doping the n-type impurity includes forming the doped semiconductor layer 391 over the third interlayer insulating layer 387 and contacting the exposed ends of the protrusions 323PP, and diffusing the impurity from the doped semiconductor layer 391 into the protrusions 323PP of the channel layer 323.

The doped semiconductor layer 391 includes the second conductive impurity that may be the n-type impurity. As the n-type impurity diffuses from the doped semiconductor layer 391 into the protrusion 323PP, the doped area 323D is formed in the channel layer 323. A portion of the channel layer 323 into which no impurity diffuses remains as the undoped area 323U.

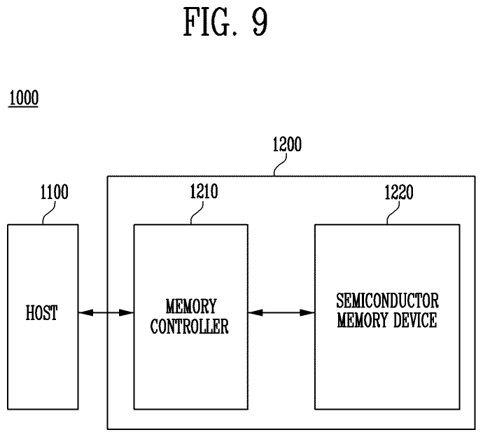

FIG. 9 is a block diagram illustrating an electronic system including a semiconductor memory device according to an embodiment of the present disclosure.

Referring to FIG. 9, an electronic system 1000 may be a computing system, a medical device, a communication device, a wearable device, a memory system, or the like. The electronic system 1000 includes a host 1100 and a storage device 1200.

The host 1100 stores data in the storage device 1200 or reads data stored in the storage device 1200 utilizing an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA (SATA) interface, a parallel-ATA (PATA) interface, a small computer system interface (SCSI), an enhanced small disk interface (ESDI), an integrated drive electronics (IDE) interface, a Firewire interface, a universal flash storage (UFS) interface, and a nonvolatile memory express (NVMe) interface.

The storage device 1200 includes a memory controller 1210 and a semiconductor memory device 1220. In an embodiment, the storage device 1200 may be configured to form a solid state drive (SSD), a universal serial bus (USB) memory, and so forth.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. The semiconductor memory device 1220 may include a channel layer and a source select line surrounding the side wall of a portion of the channel layer, as described above with reference to FIG. 3A, FIG. 3B, and FIG. 4. The portion of the channel layer may be locally doped with a p-type impurity, as described above with reference to FIG. 3B, or a gate insulating layer may be interposed between the portion of the channel layer and the source select line, as described above with reference to FIG. 4, thus enabling the threshold voltage of a source select transistor coupled to the source select line to be controlled.

According to various embodiments of the present disclosure, because no data storage layer is interposed between a source select line and a channel layer, a program operation or an erase operation for controlling the threshold voltage of a source select transistor need not be performed.

What is claimed is:

1. A semiconductor memory device comprising:
a channel layer including a first area, a second area extending from the first area in a first direction, and a third area extending from the second area in the first direction, wherein the second area contains a p-type impurity;
a plurality of word lines stacked along a side wall of the first area and spaced apart from each other in the first direction;
a source select line spaced apart from the plurality of word lines in the first direction, at least a section of the source select line surrounding at least a part of the second area in the channel layer;
a data storage layer interposed between the plurality of word lines and the channel layer; and
a tunnel insulating layer interposed between the data storage layer and the channel layer and extending in the first direction beyond the data storage layer such that the tunnel insulating layer is interposed between the channel layer and the source select line.

2. The semiconductor memory device according to claim 1,
wherein the second area contains a higher concentration of the p-type impurity than the first area and the third area.

3. The semiconductor memory device according to claim 1,
wherein a boundary between the first area and the second area in the channel layer is located at a level between the source select line and a first word line, and
wherein the first word line is one closest to the source select line among the plurality of word lines.

4. The semiconductor memory device according to claim 1,
wherein the source select line comprises a first surface facing the plurality of word lines and a second surface opposite to the first surface; and
wherein a boundary between the second area and the third area in the channel layer is located at a level between the first surface and the second surface of the source select line.

5. The semiconductor memory device according to claim 1, wherein the first area in the channel layer is an undoped area.

6. The semiconductor memory device according to claim 1, wherein the second area in the channel layer contains an n-type impurity and the p-type impurity.

7. The semiconductor memory device according to claim 1, further comprising a doped semiconductor layer spaced apart from the source select line in the first direction and contacting the third area in the channel layer, wherein the third area in the channel layer and the doped semiconductor layer each contain an n-type impurity as a majority carrier.

8. The semiconductor memory device according to claim 1, wherein the second area in the channel layer has a threshold voltage higher than the threshold voltage of the third area.

9. The semiconductor memory device according to claim 1,
wherein the source select line comprises a first surface facing the plurality of word lines and a second surface opposite to the first surface;
wherein the data storage layer contacts the first surface of the source select line; and
wherein the tunnel insulating layer protrudes beyond the second surface of the source select line in the first direction.

10. The semiconductor memory device according to claim 9, further comprising a blocking insulating layer interposed between the plurality of word lines and the data storage layer, wherein the blocking insulating layer contacts the first surface of the source select line.

11. The semiconductor memory device according to claim 1, further comprising:
a doped semiconductor layer spaced apart from the source select line in the first direction and contacting the third area in the channel layer;
a first interlayer insulating layer disposed between the source select line and the plurality of word lines;
a second interlayer insulating layer disposed between each pair of consecutive word lines of the plurality of word lines; and
a third interlayer insulating layer disposed between the source select line and the doped semiconductor layer.

12. A semiconductor memory device comprising:
a channel layer extending in a first direction;
a plurality of word lines stacked along a side wall of the channel layer and spaced apart from each other in the first direction;
a source select line spaced apart from the plurality of word lines in the first direction and spaced apart from the side wall of the channel layer in a second direction perpendicular to the first direction;
a doped semiconductor layer spaced apart from the source select line in the first direction and contacting an end of the channel layer;
a gate insulating layer including a first member interposed between the channel layer and the source select line; and
a data storage layer interposed between the plurality of word lines and the channel layer;
wherein the first member of the gate insulating layer is aligned with the data storage layer in the first direction.

13. The semiconductor memory device according to claim 12,
wherein the source select line comprises a first surface facing the plurality of word lines and a second surface facing the doped semiconductor layer; and
wherein the gate insulating layer further comprises a second member extending along the first surface of the source select line.

14. The semiconductor memory device according to claim 12, wherein, in the second direction, the first member of the gate insulating layer is formed with a thickness greater than a thickness of the data storage layer.

15. The semiconductor memory device according to claim 12, further comprising a tunnel insulating layer interposed between the side wall of the channel layer and the data storage layer and extending in the first direction to be interposed between the first member of the gate insulating layer and the channel layer.

16. The semiconductor memory device according to claim 15, wherein, in the second direction, the first member of the gate insulating layer is formed with a thickness greater than a thickness of the tunnel insulating layer.

17. The semiconductor memory device according to claim 12, further comprising a blocking insulating layer interposed between the plurality of word lines and the data storage layer, wherein the first member of the gate insulating layer is aligned with the blocking insulating layer in the first direction.

18. The semiconductor memory device according to claim 17, wherein, in the second direction, the first member of the gate insulating layer is formed with a thickness greater than a thickness of the blocking insulating layer.

19. The semiconductor memory device according to claim 12,
wherein the source select line comprises a first surface facing the plurality of word lines and a second surface facing the doped semiconductor layer;
wherein the channel layer comprises an undoped area surrounded by the plurality of word lines and a doped area distributed from the end of the channel layer toward the undoped area; and
wherein a boundary between the undoped area and the doped area is located at a level between the first surface of the source select line and the second surface of the source select line.

20. The semiconductor memory device according to claim 19, wherein the doped area of the channel layer and the doped semiconductor layer each contain an n-type impurity as a majority carrier.

21. The semiconductor memory device according to claim 12, further comprising:
a first interlayer insulating layer disposed between the source select line and the plurality of word lines;
a second interlayer insulating layer disposed between each pair of consecutive word lines of the plurality of word lines; and
a third interlayer insulating layer disposed between the source select line and the doped semiconductor layer.

22. A semiconductor memory device comprising:
a channel layer extending in a first direction and including a first area having a doped impurity;
a plurality of word lines stacked along the channel layer and spaced apart from each other in the first direction;
a source select line spaced apart from the plurality of word lines in the first direction and spaced apart from the side wall of the channel layer in a second direction perpendicular to the first direction;
a doped semiconductor layer contacting an end of the channel layer;
a gate insulating layer including a first member interposed between the channel layer and the source select line; and
wherein the first area is at least partially disposed at a level of the source select line; and
wherein a thickness of the gate insulating layer establishes threshold voltage characteristics for a source select transistor associated with the source select line.

23. A method of manufacturing a semiconductor memory device, the method comprising:
forming a stacked body including a first interlayer insulating layer that has a first surface and a second surface facing in opposite directions and a plurality of word lines alternately stacked with a plurality of second interlayer insulating layers over the first surface of the first interlayer insulating layer;
forming a cell plug including a channel layer that extends through the stacked body and has a protrusion extending beyond the second surface of the first interlayer insulating layer, a tunnel insulating layer including a first area interposed between the channel layer and the stacked body and a second area covering the protrusion of the channel layer, a data storage layer extending along the first area and the second area of the tunnel insulating layer, and a blocking insulating layer extending along the data storage layer, wherein the data storage layer is interposed between the tunnel insulating layer and the blocking insulating layer;
sequentially removing a portion of the blocking insulating layer and a portion of the data storage layer to expose the second area of the tunnel insulating layer;
forming a preliminary doped area in the channel layer by injecting an impurity of a first conductivity type into an area of the channel layer surrounded by at least the second surface of the first interlayer insulating layer; and
forming a source select line over the second surface of the first interlayer insulating layer.

24. The method according to claim 23, further comprising:
forming a third interlayer insulating layer over the source select line;
exposing an end of the protrusion of the channel layer by removing an end of the second area of the tunnel insulating layer; and
doping an impurity of a second conductivity type opposite to the first conductivity type in each of the protrusion of the channel layer and the preliminary doped area.

25. The method according to claim 24, further comprising forming a doped semiconductor layer contacting the end of the protrusion of the channel layer.

26. The method according to claim 25, wherein:
the doped semiconductor layer comprises the impurity of the second conductivity type, and
the impurity of the second conductivity type diffuses from the doped semiconductor layer toward the preliminary doped area, such that the protrusion of the channel layer and the preliminary doped area are doped with the impurity of the second conductivity type.

27. The method according to claim 24, wherein:
the impurity of the first conductivity type is a p-type impurity, and
the impurity of the second conductivity type is an n-type impurity.

28. A method of manufacturing a semiconductor memory device, the method comprising:
forming a stacked body including a first interlayer insulating layer that has a first surface and a second surface facing in opposite directions and a plurality of word lines alternately stacked with a plurality of second interlayer insulating layers over the first surface of the first interlayer insulating layer;
forming a cell plug including a channel layer that extends through the stacked body and has a protrusion extending beyond the second surface of the first interlayer insulating layer, a tunnel insulating layer including a first area interposed between the channel layer and the stacked body and a second area covering the protrusion of the channel layer, a data storage layer extending along the first area and the second area of the tunnel insulating layer, and a blocking insulating layer extending along the data storage layer, wherein the data storage layer is interposed between the tunnel insulating layer and the blocking insulating layer;
sequentially removing a portion of the blocking insulating layer and a portion of the data storage layer to expose the second area of the tunnel insulating layer;
forming a gate insulating layer that covers the exposed second area of the tunnel insulating layer; and
forming a source select line over the gate insulating layer.

29. The method according to claim 28, further comprising:
forming a third interlayer insulating layer over the source select line;
removing a portion of the third interlayer insulating layer, a portion of the gate insulating layer, and a portion of the second area of the tunnel insulating layer to expose an end of the protrusion of the channel layer; and
doping a portion the protrusion of the channel layer with an n-type impurity.

30. The method according to claim 29, further comprising forming a doped semiconductor layer contacting the end of the protrusion of the channel layer.

31. The method according to claim 30, wherein:
the doped semiconductor layer comprises the n-type impurity, and
the n-type impurity diffuses from the doped semiconductor layer into the protrusion of the channel layer, such that the protrusion is doped with the n-type impurity.
